(19) United States
(12) Patent Application Publication
(10) Pub. No.: US 2002/0007744 A1
(43) Pub. Date: Jan. 24, 2002

(54) Protective pocket and method of making a protective pocket

(76) Inventor: Hans Eppinger, Arlington Hts, IL (US)

Correspondence Address: Douglas J. Hura, DENTSPLY INTERNATIONAL INC., 570 West College Avenue, York, PA, 17405, US

(21) Appl. No.: 09/740,107

(22) Filed: Dec. 18, 2000

Related U.S. Application Data
(60) Provisional application No. 60/172,503, filed on Dec. 17, 1999.

(51) Int. Cl. B41L 7/00; B41F 7/00; B41L 9/00; B41L 11/00; B32B 31/00; G03F 7/00

(52) U.S. Cl. 101/130; 430/309; 156/251

(57) ABSTRACT

A protective pocket (10) is formed from a bottom sheet (11) adhesively bonded to a top sheet (12) to form a pocket therebetween. Adhesive pattern (13) is placed onto the sheets (11, 12) by otherwise conventional printing techniques.

### TECHNICAL FIELD

The present invention is directed toward protective pockets. Further, the invention is directed toward a protective pocket made from a plastic sheet which is adhesively affixed or welded to a second sheet to form a pocket between the two sheets. Specifically, the invention is directed toward such a pocket wherein the adhesive is put down by printing techniques. The invention is also directed toward a method of forming such a protective pocket.

Flexographic and other printed techniques are well known in the art. Such printing techniques are disclosed for example in U.S. Pat. Nos. 5,998,098; 5,997,677; 5,994,026; 5,979,315; 5,948,594 and 4,928,588, all of which are hereby incorporated by reference for their specific and general disclosures of printing techniques.

A need exists therefore for a protective pocket, such as those used to hold and protect dental films, which can be efficiently and economically manufactured.

### BACKGROUND OF THE INVENTION

Currently protectors made of transparent plastic, preferably vinyl, are widely used to protect documents, thin objects as well as photographic and dental X-ray films for archival purposes. Pockets are formed by joining two sheets of transparent film in selected areas to form a pocket open on at least one side to permit the insertion of thin objects. The films are joined using ultrasonic or radio frequency welding technology. Both methods have limitations. In each case, the heat generated during the welding process softens the films to a point where both contacting film surfaces fuse. Ultrasonic technology only generates sufficient energy for a relatively small bonding surface area and requires a critical adjustment of weld equipment parameters to prevent liquefaction and subsequent evaporation of the plastic in the weld area. Radio frequency welding permits the bonding of larger areas and does not require as tight a control of weld equipment parameters. However, welding with radio frequencies requires considerably more process time than using ultrasonic frequencies. Special tooling must be developed for each weld process sometimes at a considerable expense depending on film thickness. The requirements for a tight control of process parameters increase significantly with thinner films to a point where very thin plastic films cannot be joined economically using the described welding technologies.

### DISCLOSURE OF THE INVENTION

It is therefore, an object of the present invention to provide a protective pocket. It is another object of the invention to provide such a pocket which is manufactured using printing techniques. These and other objects of the invention which will become apparent from the following disclosure are carried out by the invention as hereinafter described.

### DISCUSSION OF THE DRAWING

FIG. 1 is a perspective view of a plastic protective pocket, formed according to the concepts of the present invention.

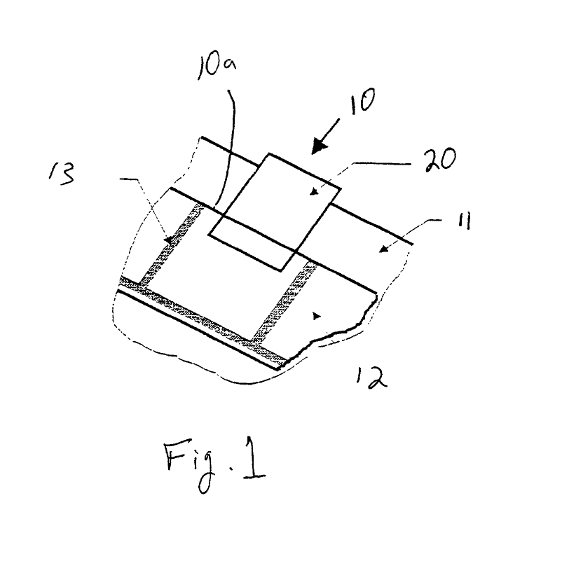

### DESCRIPTION OF THE PREFERRED EMBODIMENTS

A protective pocket embodying the concepts of the present invention is generally shown by the number 10 on the attached drawing. Pocket 10 preferably is formed with a bottom sheet 11, a top sheet 12 and an adhesive pattern 13 therebetween. Although

It will be appreciated that the product and method according to the present invention has several advantages. First, very thin plastic films can be joined using the adhesive method. The development of special equipment and tooling is not required for bonding the thin films. Further, the geometry of the adjoining pattern does not have any limitations related to size or complexity. The tooling costs of such a product would be greatly reduced as compared to conventional adhesive bonding of plastic sheets. Further still, printing and adjoining of plastic films can be done on a single piece of machinery, and the adhesive joining requires only a fraction of the time needed for conventional ultrasonic or radio frequency welding.

It should be apparent therefore that the protective pocket as described hereinabove, accomplishes the objects of the invention. It will be appreciated that the protective pocket discussed and described above may be changed or varied as to for example, the number of sheets employed to make the pocket, the size, shape or configuration of the pocket, the type of adhesive chosen, and the particulars of the technique for putting down the adhesive, without departing from the scope and spirit of the present invention.

What is claimed is:

1. A protective pocket comprising:
at least a first and a second layer of pocket material, wherein said first and second layers are joined by an adhesive placed upon at least one of said first or second sheets by a printing technique.

2. A method of preparing a protective pocket comprising the steps of:
adhering a first layer of pocket material to a second layer of pocket material with an adhesive, wherein said adhesive is placed upon at least one of said first and second layers by a printing technique.

3. A method as in claim 2, wherein said printing technique is flexographic printing.
